(19) United States
(12) Patent Application Publication
(10) Pub. No.: US 2019/0238125 A1
(43) Pub. Date: Aug. 1, 2019

(54) SAMPLING CIRCUITRY WITH TEMPERATURE INSENSITIVE BANDWIDTH

(71) Applicant: MACOM Technology Solutions Holding, Inc., Lowell, MA (US)

(72) Inventors: Yanfei CHEN, Santa Clara, CA (US); Hiva HEDAYATI, Santa Clara, CA (US)

(21) Appl. No.: 16/121,449

(22) Filed: Sep. 4, 2018

Related U.S. Application Data
(60) Provisional application No. 62/623,435, filed on Jan. 29, 2018.

(51) Int. Cl. H03K 17/14; G11C 27/02

(52) U.S. Cl. CPC H03K 17/145; G11C 27/02

(57) ABSTRACT

A sampling circuitry with a temperature insensitive bandwidth can include a temperature dependent current source, a source-follower amplifier, a storage element and a clocked transmission gate. The source-follower amplifier can be biased by the temperature dependent current source. The source-follower amplifier can be coupled to an input signal node, and the clocked transmission gate can be coupled to a clock signal. The clocked transmission gate can be coupled between an output of the source-follower amplifier and a combination of the storage element and an output signal node. A temperature-based variance in an output impedance of source-follower amplifier, an on-resistance of the clocked transmission gate and the capacitance of the storage element can be substantially cancelled by the temperature dependent current source.

### CROSS-REFERENCE TO RELATED APPLICATIONS

This Application claims the benefit of U.S. Patent Provisional Application No. 62/623,435 filed Jan. 29, 2018, which is incorporated herein in its entirety.

### BACKGROUND OF THE INVENTION

Computing systems have made significant contributions toward the advancement of modern society and are utilized in a number of applications to achieve advantageous results. Numerous devices, such as desktop personal computers (PCs), laptop PCs, tablet PCs, netbooks, smart phones, servers, and the like have facilitated increased productivity and reduced costs in communicating and analyzing data in most areas of entertainment, education, business, and science. One common aspect of computing systems is the communication of data within and between computing systems.

Sampling circuits are commonly used in data communication sub-systems. A sampling circuit can sample a voltage level of a signal and hold its value for a period of time. There are applications that require the sampling circuit to have a constant bandwidth across a range of temperatures. However, the bandwidth of conventional sampling circuits can decrease as the operating temperature of the sampling circuit increases. Accordingly, there is a continuing need for improved sampling circuits.

### SUMMARY OF THE INVENTION

The present technology may best be understood by referring to the following description and accompanying drawings that are used to illustrate embodiments of the present technology directed toward a sampling circuit with a substantially temperature insensitive bandwidth. In one embodiment, the sampling circuit can include a source-follower coupled transistor, a hold capacitor, and a clocked sampling transistor. The source-follower coupled transistor can be biased by a temperature dependent current source. A gate of the source-follower coupled transistor can be coupled to an input node of the sampling circuit, and the hold capacitor can be coupled to an output node of the sampling circuit. The cocked sampling transistor can be coupled between a source of the source-follower transistor and the hold capacitor. The source-follower coupled transistor and the clocked sampling transistor can be sized so that a combination of variances in an output impedance of the source-follower coupled transistor and an on-resistance of the clocked sampling transistor is dominated by a variance in a bias current of the temperature dependent current source. In one implementation, the bias current of the temperature dependent current source can be a Proportional-To-Absolute-Temperature (PTAT) current.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

Embodiments of the present technology are illustrated by way of example and not by way of limitation, in the figures of the accompanying drawings and in which like reference numerals refer to similar elements and in which:

FIG. 1 shows a block diagram of a sampling circuit, in accordance with aspects of the present technology.

FIG. 2 shows a block diagram of a sampling circuit, in accordance with aspects of the present technology.

FIG. 3 shows a block diagram of an exemplary temperature dependent current source, in accordance with aspects of the present technology.

FIG. 4 shows a block diagram of a sampling circuit, in accordance with aspects of the present technology.

FIG. 5 shows a simulation of bandwidth versus temperature for an exemplary sampling circuit, in accordance with aspects of the present technology.

### DETAILED DESCRIPTION OF THE INVENTION

Reference will now be made in detail to the embodiments of the present technology, examples of which are illustrated in the accompanying drawings. While the present technology will be described in conjunction with these embodiments, it will be understood that they are not intended to limit the invention to these embodiments. On the contrary, the invention is intended to cover alternatives, modifications and equivalents, which may be included within the scope of the invention as defined by the appended claims. Furthermore, in the following detailed description of the present technology, numerous specific details are set forth in order to provide a thorough understanding of the present technology. However, it is understood that the present technology may be practiced without these specific details. In other instances, well-known methods, procedures, components, and circuits have not been described in detail as not to unnecessarily obscure aspects of the present technology.

Some embodiments of the present technology which follow are presented in terms of routines, modules, logic blocks, and other symbolic representations of operations on data within one or more electronic devices. The descriptions and representations are the means used by those skilled in the art to most effectively convey the substance of their work to others skilled in the art. A routine, module, logic block and/or the like, is herein, and generally, conceived to be a self-consistent sequence of processes or instructions leading to a desired result. The processes are those including physical manipulations of physical quantities. Usually, though not necessarily, these physical manipulations take the form of electric or magnetic signals capable of being stored, transferred, compared and otherwise manipulated in an electronic device. For reasons of convenience, and with reference to common usage, these signals are referred to as data, bits, values, elements, symbols, characters, terms, numbers, strings, and/or the like with reference to embodiments of the present technology.

It should be borne in mind, however, that all of these terms are to be interpreted as referencing physical manipulations and quantities and are merely convenient labels and are to be interpreted further in view of terms commonly used in the art. Unless specifically stated otherwise as apparent from the following discussion, it is understood that through discussions of the present technology, discussions utilizing the terms such as “receiving,” and/or the like, refer to the actions and processes of an electronic device such as an electronic computing device that manipulates and transforms data. The data is represented as physical (e.g., electronic) quantities within the electronic device's logic circuits, registers, memories and/or the like, and is transformed into other data similarly represented as physical quantities within the electronic device.

In this application, the use of the disjunctive is intended to include the conjunctive. The use of definite or indefinite articles is not intended to indicate cardinality. In particular, a reference to “the” object or “a” object is intended to denote also one of a possible plurality of such objects. It is also to be understood that the phraseology and terminology used herein is for the purpose of description and should not be regarded as limiting.

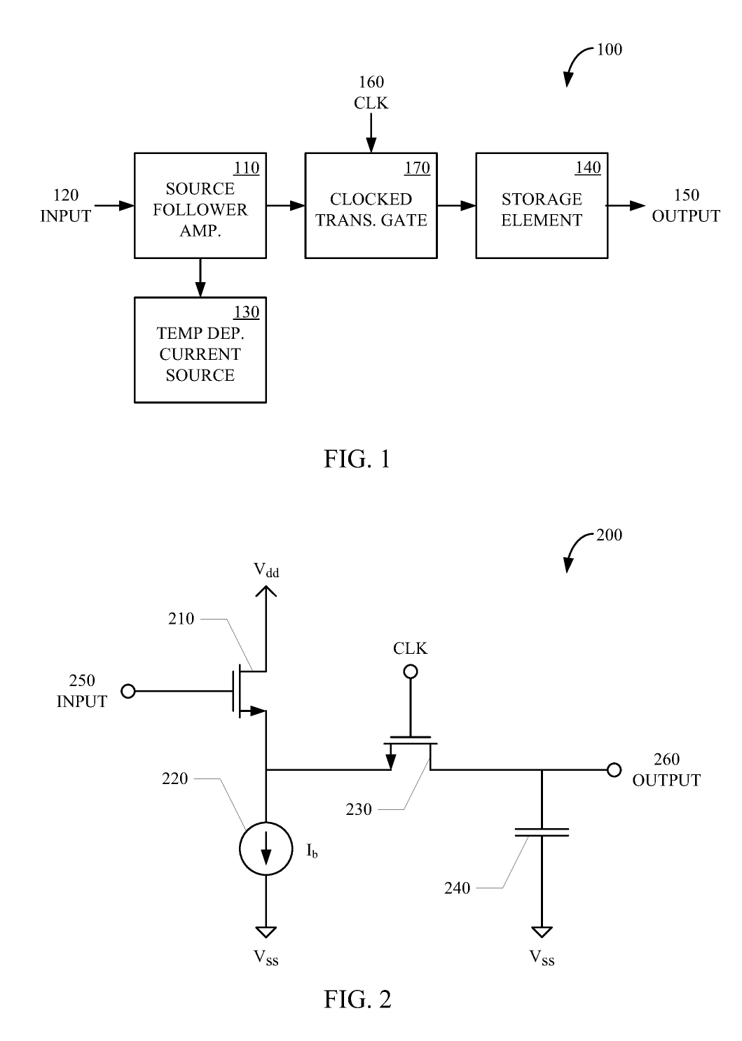

Referring to FIG. 1, a block diagram of a sampling circuit, in accordance with aspects of the present technology, is shown. The sampling circuit 100 can include a source-follower amplifier 110 coupled to an input signal node 120. The source-follower amplifier 110 can be biased by a temperature dependent current source 130. A storage element 140 can be coupled to an output signal node 150, and a clocked 160 transmission gate 170 can be coupled between an output of the source-follower amplifier 110 and the storage element 140.

The source-follower amplifier 110 can produce a signal at the input of the clocked transmission gate 170 from the signal received at the input node 120. The source-follower amplifier 110 can have an output impedance of (1/gₘ). During an ‘on-state’ of the clock signal 160, the clocked transmission gate 170 can pass the signal at the output of the source-follower amplifier 110 to the storage element 140. During the on state, the clocked transmission gate 170 can have an on-resistance of Rₒₙ. During the ‘off-state’ of the clock signal 160, the storage element 140 can hold the output node 150 at the signal level of the signal passed by the clocked transmission gate 170. In an exemplary implementation, the input node 120 can vary between a first signal level Vᵢₙ₊ and a second signal level Vᵢₙ₋. When the signal at the input node 120 is at a voltage level of Vᵢₙ₊, the source-follower amplifier 110 can produce a signal having a voltage level of approximately Vᵢₙ₊ at the input to the clocked transmission gate 170. During a high state of a clock signal 160, the clocked transmission gate 170 can pass the voltage level of approximately Vᵢₙ₊ to the storage element 140 and drive the output node 150 to the voltage level of approximately Vᵢₙ₊. When the clock signal 160 switches to a low state, the storage element 140 can maintain the output node 150 at the voltage level of approximately Vᵢₙ₊. When the signal at the input node 120 transitions to a voltage level of Vᵢₙ₋, the source-follower amplifier 110 can produce a signal having a voltage level of approximately Vᵢₙ₋ at the input to the clocked transmission gate 170. During another high state of the clock signal 160, the clocked transmission gate 170 can pass the voltage level of approximately Vᵢₙ₋ to the storage element 140 and drive the output node 150 to the voltage level of approximately Vᵢₙ₋. When the clock signal 160 switches to a low state, the storage element 140 can maintain the output node 150 at the voltage level of approximately Vᵢₙ₋.

In aspects, the bias current of the temperature dependent current source 130 supplied to the source-follower amplifier 110 can vary as a function of the temperature of the sampling circuit 100. In addition, the sampling circuit 100 can be characterized by a time constant (τ) that is a function of an output impedance (1/gₘ) of the source-follower amplifier 110, an on-resistance (Rₒₙ) of the clocked transmission gate 170, and a capacitance (C) of the storage element 140. The output impedance (1/gₘ) of the source-follower amplifier 110 and on-resistance (Rₒₙ) of the clocked transmission gate 170 can vary with the operating temperature of the sampling circuit 100. The temperature variance in the output impedance (1/gₘ) of the source-follower amplifier 110 and on-resistance (Rₒₙ) of the clocked transmission gate 170 can be determined by one or more manufacturing parameters. In such case, a variance in the time constant (τ) of the sampling circuit 100 can be substantially cancelled by the temperature variance in the bias current from the temperature dependent current source 130. Therefore, by manufacturing the source-follower amplifier 110 and the clocked transmission gate 170 according to one or more specified manufacturing parameters that variance in the gain of the source-follower amplifier 110 and the variance in the on-resistance of the clocked transmission gate 170 can cancel each other out in the bandwidth of the sampling circuit 100. In such case, the bandwidth of the sampling circuit 100 can be substantially insensitive to variations in the operating temperature of the sampling circuit 100.

Referring now to FIG. 2, a block diagram of a sampling circuit, in accordance with aspects of the present technology, is shown. The sampling circuit 200 can include a source-follower coupled transistor 210 (also known as a source-follower amplifier or common-drain amplifier), a temperature dependent current source 220, a clocked sampling transistor 230, and a hold capacitor 240.

A gate of the source-follower coupled transistor 210 can be coupled to an input node 250. A drain of the source-follower coupled transistor 210 can be coupled to a first supply potential (V_{dd}). The source-follower coupled transistor 210 can also be biased by the temperature dependent current source 220 coupled to a source of the source-follower coupled transistor 210. A gate of the clocked sampling transistor 230 can be coupled to a clock signal. A source of the clocked sampling transistor 230 can be coupled to the source of the source-follower coupled transistor 210. A drain of the clocked sampling transistor 230 can be coupled to an output node 260. The hold capacitor 240 can be coupled between the output node 260 and a second supply potential (V_{SS}). The source-follower transistor 210 and the clocked sampling transistor 230 can be n-type enhancement mode Metal Oxide Semiconductor Field Effect Transistors (MOSFET). The temperature dependent current source 220 can be a Proportional-To-Absolute (PTAT) current source.

In an exemplary implementation, the input node 250 can vary between a first signal level Vᵢₙ₊ and a second signal level Vᵢₙ₋. When the signal at the input node 250 is at a voltage level of Vᵢₙ₊, the source-follower coupled transistor 210 can produce a signal having a voltage level of Vᵢₙ₊−V_{GS} at the input to the clocked transmission gate 170. During a high state of a clock signal 160, the clocked transmission gate 170 can pass a voltage level of Vᵢₙ₊−V_{GS}−V_{TH} to the storage element 140 and drive the output node 150 to the voltage level of Vᵢₙ₊−V_{GS}−V_{TH}. When the clock signal 160 switches to a low state, the storage element 140 can maintain the output node 150 at the voltage level of approximately Vᵢₙ₊−V_{GS}−V_{TH}. When the signal at the input node 120 transitions to a voltage level of Vᵢₙ₋, the source-follower amplifier 110 can produce a signal having a voltage level of Vᵢₙ₋−V_{GS} at the input to the clocked transmission gate 170. During another high state of the clock signal 160, the clocked transmission gate 170 can pass a voltage level of Vᵢₙ₋−V_{GS}−V_{TH} to the storage element 140 and drive the output node 150 to the voltage level of approximately Vᵢₙ₋−V_{GS}−V_{TH}. When the clock signal 160 switches to a low state, the storage element 140 can maintain the output node 150 at the voltage level of approximately Vᵢₙ₋−V_{GS}−V_{TH}.

The bandwidth of the sampling circuit 200 can be determined as a function of the output impedance (1/gₘ) of the source-follower coupled transistor 210, the on-resistance (Rₒₙ) of the clocked sampling transistor 230, and the capacitance of the hold capacitor 240. The output impedance (1/gₘ) of the source-follower coupled transistor 210 is provided in Equation 1, and the on-resistance (Rₒₙ) of the clocked sampling transistor 230 in Equation 2, as follows.

$$\begin{matrix}\frac{1}{{g}_{m}} = \frac{1}{\sqrt{2 \times β \times {I}_{b}}} & ( 1 ) \\ {R}_{on} = \frac{1}{β ( {V}_{GS} - {V}_{TH} )} & ( 2 )\end{matrix}$$

Wherein β is the gain, V_{GS} is the gate-to-source voltage, V_{TH} is the threshold voltage, and I_{b} is the bias current of the source-follower coupled transistor 210. Generally, when the temperature (T) increases, the gain (β) and the threshold voltage (V_{TH}) of the source-follower coupled transistor 210 decrease. Therefore, if the bias current (I_{b}) of the source-follower transistor 210 is constant, both the output impedance (1/gₘ) of the source-follower coupled transistor 210 and the on-resistance (Rₒₙ) of the clocked sampling transistor 230 increases with temperature (T). When the output impedance (1/gₘ) of the source-follower coupled transistor 210 and the on-resistance (Rₒₙ) of the clocked sampling transistor 230 increases with temperature (T), the bandwidth of the sampling circuit 200 decreases. However, if the source-follower coupled transistor 210 is biased with a current source that varies proportional to the operating temperature of the sampling circuit 200 the variance in the output impedance (1/gₘ) can be dominated by the bias current (I_{b}) rather than the gain (β). Therefore, sizing the source-follower coupled transistor 210 and the clocked sampling transistor 230 can be utilized to have variations in the output impedance (I/gₘ) of the source-follower coupled transistor 210 and the on-resistance (Rₒₙ) of the clocked sampling transistor 230 with temperature (T) cancel each other.

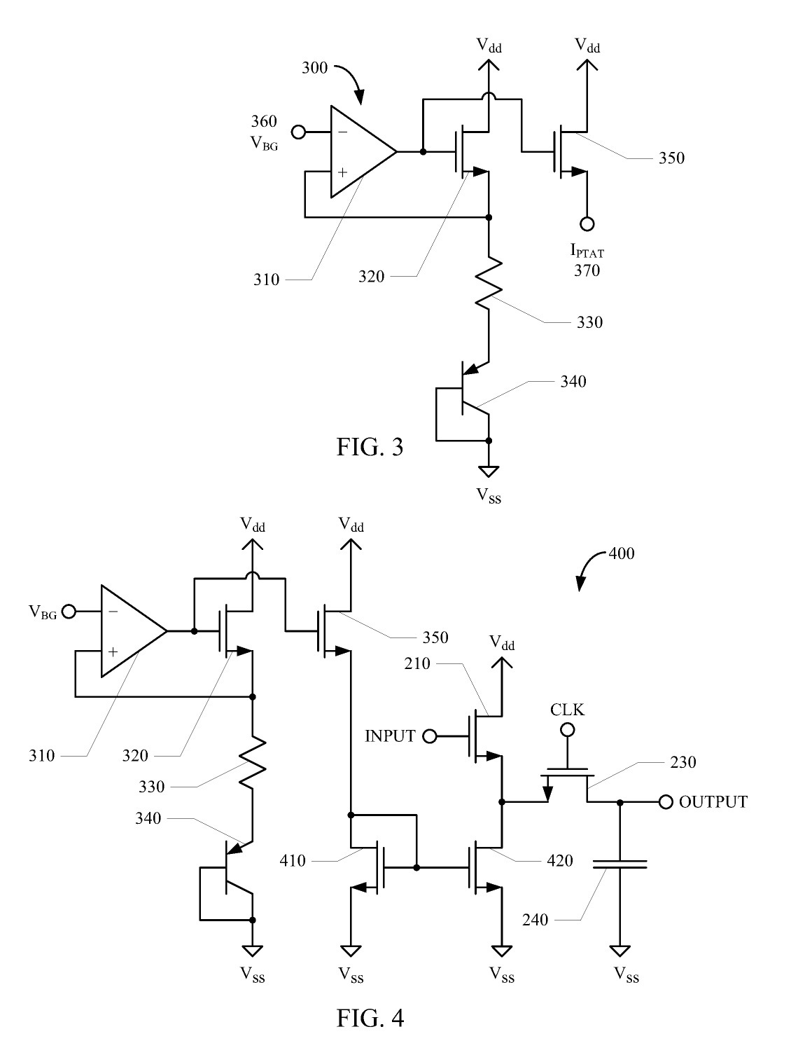

Referring now to FIG. 3, a block diagram of an exemplary temperature dependent current source, in accordance with aspects of the present technology, is shown. The temperature dependent current source can be a Proportional-To-Absolute (PTAT) current source 300. The PTAT current source 300 can include an operational amplifier 310, a first transistor 320, a resistor 330, a second transistor 340, and a third transistor 350. In one implementation, the first and third transistors can be n-type enhancement mode MOSFETs and the second transistor can be pnp Bipolar Junction Transistor (BJT)

An inverting input terminal of the operational amplifier 310 can be coupled to a constant voltage source such as a bandgap reference voltage (V_{BG}). The bandgap reference voltage (V_{BG}) is substantially constant as a function of temperature (T). An output terminal of the operational amplifier can be coupled to a gate of the first transistor 320. A drain of the first transistor can be coupled to a first supply potential (V_{dd}). A source of the first transistor 320 can be coupled to the inverting input terminal of the operational amplifier 310 and a first terminal of the resistor 330. The second terminal of the resistor 330 can be coupled to an emitter of the second transistor 340. A base and a collector of the second transistor can be coupled to a second supply potential (V_{SS}).

During a steady state condition, the operational amplifier 310 can drive the gate of the first transistor 310 so that a potential of V_{BG} is generated at the source of the first transistor 320 and the non-inverting input terminal of the operational amplifier 310. The potential of V_{BG} at the source of the first transistor 320 can also cause the second transistor 340 to turn on and conduct current between the emitter and collector of the second transistor 340. The voltage generated by the operational amplifier 310 at the gates of the first and third transistors 320, 350 can be approximately the sum of the bandgap reference voltage (V_{BG}) and the threshold voltage (V_{TH}) of the first transistor 320. The threshold voltage (V_{TH}) is the voltage at which the first and second transistors 320, 350 will turn on and conduct current. The voltage generated by the operational amplifier 310 at the gates of the first and third transistors 320, 350 can cause substantially the same current that flows through the first transistor 320 to also flow through the second transistors 350. However, the current flowing through the first and third transistors 320, 350 will decrease as a function of an increase in the operating temperature of the first and third transistors 320, 350. Therefore, the current flowing from the output of the temperature dependent current source can be proportional to the operational temperate. In one implementation, the current can be a Proportional-to-Absolute-Temperature (PTAT) current.

The exemplary temperature dependent current source of FIG. 3 is not intended to be limiting. Instead, numerous other implementations of temperature dependent current sources can be utilized in the sampling circuits in accordance with aspects of the present technology.

Referring now to FIG. 4, a block diagram of a sampling circuit, in accordance with aspects of the present technology, is shown. The sampling circuit 400 can include a temperature dependent current source sub-circuit 310-350 coupled to a sampling sub-circuit 310-240 by a current mirror sub-circuit 410-420.

The temperature dependent current source sub-circuit can be a Proportional-To-Absolute (PTAT) current source including an operation amplifier 310, a first transistor 320, a resistor 330, a second transistor 340, and a third transistor 350. The current source can generate a PTAT current (I_{PAT}) that decreases as a function of increases in the operating temperature as described above with respect to FIG. 3.

The current mirror sub-circuit can include fourth and fifth transistors 410, 420. The fifth transistor 420 provides a bias current to the sampling sub-circuit that is substantially equal to the PTAT current (I_{PTAT}) flowing through the fourth transistor 410. Therefore, the bias current provided to the sampling sub-circuit will be the PTAT current (I_{PTAT}) that decreases as a function of increases in the operating temperature.

The sampling sub-circuit can include sixth and seventh transistors 210, 230 and a hold capacitor 240. The sampling sub-circuit can sample an input signal to generate an output signal with a substantially temperature insensitive bandwidth as described above with respect to FIG. 2. In aspects, the source-follower transistor 210 can be sized so that temperature-based variances in an output impedance (1/gₘ) of the source-follower transistor 210, and an on-resistance (Rₒₙ) of the clocked sampling transistor 230 is dominated by the temperature variance in the PTAT current (I_{PTAT}) used to bias the source-follower transistor 210. In one instance, variances in the PTAT current (I_{PTAT}) can be configured to cause variances in the output impedance (1/gₘ) of the source-follower transistor 210 and the on-resistance (Rₒₙ) of the clocked sampling transistor 230 to cancel each other out by selecting appropriate manufacturing parameters of the source-follower transistor 210 and/or the clocked sampling transistor 230.

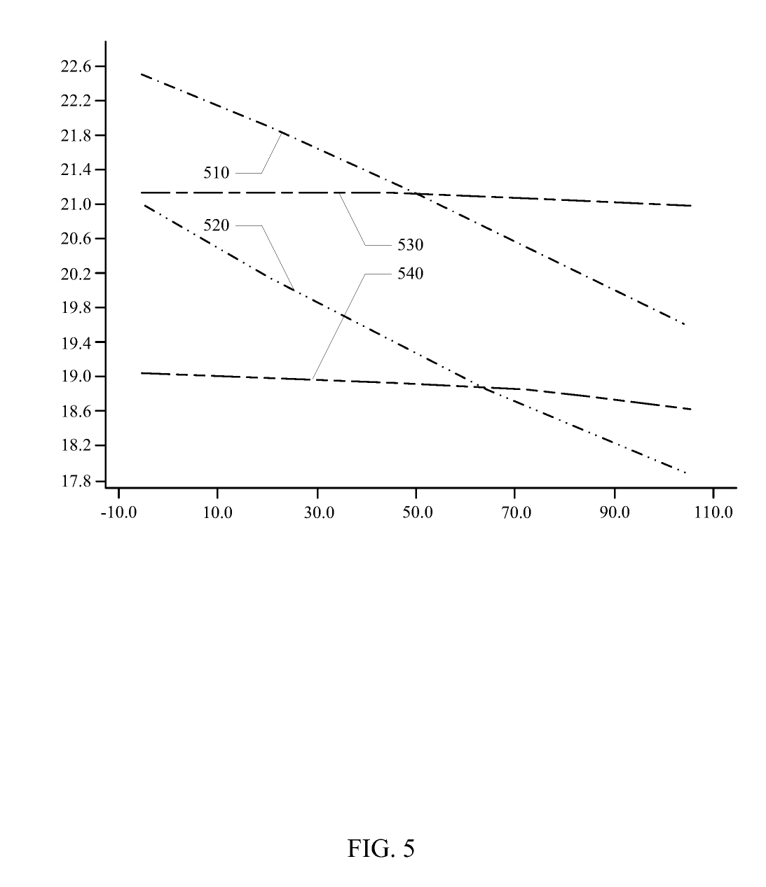

Referring now to FIG. 5, a simulation of bandwidth versus temperature for an exemplary sampling circuit, in accordance with aspects of the present technology, is shown. As illustrated, for a constant bias current (I_{c}) the bandwidth 510, 520 drops off as the temperature increases. In contrast, the bandwidth 530, 540 is substantially constant for a bias current that is Proportional-To-Absolute-Temperature (I_{PTAT}). The bandwidth of the sampling circuit can be substantially constant with respect to temperature when the combination of the temperature variance of the on-resistance of a clocked transmission gate and the output impedance of a source-follower amplifier of the sampling circuit is configured to cancel each other out. In aspects, the variance in the on-resistance and output impedance can advantageously be configured to cancel each other by scaling one or more manufacturing parameters of the clock transmission gate and/or the source-follower amplifier.

The foregoing descriptions of specific embodiments of the present technology have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the present technology and its practical application, to thereby enable others skilled in the art to best utilize the present technology and various embodiments with various modifications as are suited to the particular use contemplated. It is intended that the scope of the invention be defined by the claims appended hereto and their equivalents.

What is claimed is:

1. A sampling circuit comprising:
a source-follower coupled transistor biased by a temperature dependent current source, wherein an input node is coupled to a gate of the source-follower coupled transistor;
a hold capacitor coupled to an output node; and
a clocked sampling transistor coupled between a source of the source-follower coupled transistor and the hold capacitor; and
wherein the source-follower coupled transistor and the clocked sampling transistor are sized so that a combination of variances in an output impedance of the source-follower coupled transistor and an on-resistance of the clocked sampling transistor is dominated by a variance in a bias current of the temperature dependent current source.

2. The sampling circuit of claim 1, wherein the clocked sampling transistor comprises,
a gate coupled to a clock signal;
a source coupled to a source of the source-follower coupled transistor; and
a drain coupled to the hold capacitor and the output node.

3. The sampling circuit of claim 1, wherein the hold capacitor is further coupled between the output node and a ground potential.

4. The sampling circuit of claim 1, wherein a drain of the source-follower transistor is coupled to a supply potential.

5. The sampling circuit of claim 1, wherein:
the source-follower transistor comprises a n-type enhancement mode Metal Oxide Semiconductor Field Effect transistor (MOSFET); and
the clocked sampling transistor comprises a n-type enhancement mode MOSFET.

6. The sampling circuit of claim 1, wherein the temperature dependent current source comprises a Proportional-To-Absolute-Temperature (PTAT) current source.

7. The sampling circuit of claim 6, wherein the PTAT current of the PTAT current source is a function of a bandgap voltage reference and a threshold voltage of a n-type enhancement mode Metal Oxide Semiconductor Field Effect transistor (MOSFET).

8. A sampling circuit comprising:
a temperature dependent current source providing a bias current (I_{b});
a first transistor characterized by an output impedance (1/gₘ), the first transistor including,
a gate coupled to an input node;
a drain coupled to a first potential; and
a source coupled to the temperature dependent current source;
a second transistor characterized by an on-resistance (Rₒₙ), the second transistor including,
a gate coupled to a clock signal;
a source coupled to a source of the first transistor; and
a drain coupled to an output node; and
a capacitor coupled between the output node and a second potential; and
wherein a combination of a temperature variance of the on-resistance (Rₒₙ) and a temperature variance of the output impedance (1/gₘ) is substantially cancelled by a temperature variance of the bias current (I_{b}).

9. The sampling circuit of claim 8, wherein:
the first potential comprises a supply potential; and
the second potential comprises a ground potential.

10. The sampling circuit of claim 8, wherein:
the first transistor comprises a n-type enhancement mode Metal Oxide Semiconductor Field Effect (MOSFET) transistor; and
the second transistor comprises a n-type enhancement mode MOSFET transistor.

11. The sampling circuit of claim 8, wherein the temperature dependent current source comprises a Proportional-To-Absolute-Temperature (PTAT) current source.

12. The sampling circuit of claim 8, wherein the temperature dependent current source comprises:
an operational amplifier including an inverting input terminal coupled to a bandgap voltage potential;
a third transistor including a drain coupled to the first potential, a gate coupled to an output terminal of the operational amplifier, and a source coupled to a non-inverting input terminal of the operational amplifier;
a resistor including a first terminal coupled to the source of the third transistor and the non-inverting input terminal of the operational amplifier,
a fourth transistor including an emitter coupled to a second terminal of the resistor, a base coupled to the second supply potential and a collector coupled to the second supply potential; and
a fifth transistor including a drain coupled to the first supply potential, a gate coupled to the output terminal of the operational amplifier, and a source coupled to the source of the source of the first transistor

13. The sampling circuit of claim 8, further comprising:
a sixth transistor including a drain the source of the fifth transistor, a gate coupled to the drain of the sixth transistor, and a source coupled to the second supply potential; and
a seventh transistor including a drain coupled to the source of the first transistor, a gate coupled to the gate of the sixth transistor, and a source coupled to the second supply potential.

14. A sampling circuit comprising:
a source-follower amplifier biased by a temperature dependent current source, the source-follower amplifier including an input coupled to an input signal node;
a storage element coupled to an output signal node;
a clocked transmission gate coupled between an output of the source-follower amplifier and a combination of the storage element and the output signal node; and
wherein a temperature variance in an output impedance of source-follower amplifier, an on-resistance of the clocked transmission gate and the capacitance of the storage element is substantially cancelled by a variance of the temperature dependent current source.

15. The sampling circuit of claim 14, wherein the source-follower amplifier comprises a first n-type enhancement mode Metal Oxide Semiconductor Field Effect transistor (MOSFET) including:
a gate coupled to the input signal node;
a drain coupled to a first supply potential; and
a source coupled to the temperature dependent current source.

16. The sampling circuit of claim 15, wherein the clocked transmission gate comprises a second n-type enhancement mode MOSFET including:
a gate coupled to a clock signal;
a source coupled to the source of the first n-type enhancement mode MOSFET; and
a drain coupled to a first terminal of the storage element and the output signal node.

17. The sampling circuit of claim 16, wherein the storage element comprises a capacitor including:
the first terminal coupled the drain of the second n-type enhancement MOSFET and the output signal node; and
a second terminal coupled to a second supply potential.

18. The sampling circuit of claim 17, wherein the temperature dependent current source comprises a Proportional-To-Absolute-Temperature (PTAT) current source.

19. The sampling circuit of claim 18, further comprising:
a current mirror coupling the PTAT current source to source-follower amplifier.

20. The sampling circuit of claim 18, wherein the first and second n-type enhancement mode MOSFETs are sized so that the variance in the combination of the output impedance of the first n-type enhancement mode MOSFET, the on-resistance of the second n-type enhancement mode MOSFET and the capacitance of the capacitor is substantially cancelled by variance in the PTAT current source.
